(19) United States
(12) Patent Application Publication
(10) Pub. No.: US 2002/0105351 A1
(43) Pub. Date: Aug. 8, 2002

(54) Systems and methods for testing bumped wafers

(76) Inventor: Inderjit Singh, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/777,260

(22) Filed: Feb. 5, 2001

(51) Int. Cl. G01R 31/26

(52) U.S. Cl. 324/765

(57) ABSTRACT

A bumped wafer testing setup and associated method that eliminates the need for membrane probes. The test setup includes two plates coupled together, with the first plate including openings to accommodate solder bumps contained on the bumped wafer and the second plate including a test printed circuit board insert contained therein. The test printed circuit board insert includes solder bump contacts that contact the solder bumps within the openings.

### BACKGROUND OF THE INVENTION

1. Field of the Invention

The present invention relates to systems and methods for testing semiconductor wafers, and more particularly, to systems and methods for testing solder bumped wafers without using membrane probes or conventional methods of probing solder bumps on the bumped wafers.

2. Description of the Prior Art

A primary component of semiconductor devices is a die, which is generally aone-piece item made up of, for example, silicon. Electrical contact to a die is made by either bond wires or solder bumps. A die with solder bumps already attached is commonly referred to as a bumpted die. A bumped die generally includes the die itself, the solder bumps themselves, and an “under bump” material that serves as an intermediate layer between the top surface of the die and the solder bumps. Preferably, the under bump material is one of Tw, Cu, Au or an equivalent with one or more of the materials in layer(s). The bumped dies are generally cut from bumped wafers. Thus, a wafer (e.g.silicon wafer) generally receives the under bump material and the plurality of solder bumps are placed thereon.

Testing of semiconductor devices occurs both at a wafer level and once again after the dies are diced and packaged. Currently, for wafer level testing, it is common to use membrane probes as test contacts for a bumped wafer. These probes are delicate and easily damaged if there is a loose bump or a bump that includes sharp edges. Furthermore, the membrane probe has a “tool life” and thus needs to be replaced from time to time.

Needle probes with a flat tip are another conventional means of probing bumped wafers to make electrical contact. However, needle probes tend to penetrate the solder which may result in voids in the solder after reflow, thus leading to a potential reliability problem. Additionally, the needle probe height setup is very critical to avoid solder damage. Additionally, the height of the solder bumps may vary across the wafer and thus makes it difficult to provide good contact with the needle probes. Such variation is also common from wafer to wafer. Additionally, the needle probe tends to pick up solder from the bump and it can end up on other parts of the wafer. Thus, solder debris may be seen on the wafer. A cleaning routine is therefore required to keep the needles clean. Access solder picked up by the tip can increase resistance and thus, may create invalid functional failures of the device.

### SUMMARY OF THE INVENTION

The present invention provides a method and apparatus for testing a bumped wafer. In one embodiment, the invention provides a method that includes providing a bumped wafer having a plurality of solder bumps and providing a test setup that includes at least one plate coupled thereto. The plate includes openings to accommodate the solder bumps and at least one interposer aligned with the openings. The interposer includes solder bump contacts. The method further includes contacting the test setup with the bumped wafer such that the solder bumps are within the openings of the plate and contacting the solder bump contacts with a test apparatus.

In accordance with one aspect of the present invention, the test set-up includes two plates and the first plate is made up of transparent material such as quartz or glass.

In accordance with another aspect of the present invention, the second plate is made up of a transparent material such as quartz or glass.

In accordance with a further aspect of the present invention, the solder bump contacts are gold plated.

In accordance with another aspect of the present invention, the method of testing includes hot and cold testing.

The present invention also provides a bumped wafer test setup that includes at least one plate that includes openings to accommodate the solder bumps and at least one Interposer aligned with the openings. The interposer includes solder bump contacts. The solder bumps project into the openings of the plate and contact the solder bump contacts when the setup is in use.

Thus, the present invention provides a method and test setup that allows for high speed testing and minimal test hardware setup. Furthermore, the present invention provides for the possible inclusion of hot and cold testing in a wafer level test environment. Because membrane probes are not used, there is no tool life requirement wherein probes need to be replaced after a certain number of “touchdowns”. Minimal modification is required on the current wafer prober setup. A conventional prober is capable of performing final testing on bumped wafers with modification to its wafer handling system in accordance with the present invention.

Other features and advantages of the present invention will be understood upon reading and understanding the detailed description of the preferred exemplary embodiments found herein below, in conjunction with reference to the drawings, in which like numerals represent like elements.

### BRIEF DESCRIPTION OF THE DRAWINGS

FIG. 1 is a top plan view of a bumped wafer test setup in accordance with the present invention; and

FIG. 2 is a side section view of the setup illustrated in FIG. 1.

### DETAILED DESCRIPTION OF SPECIFIC EMBODIMENTS

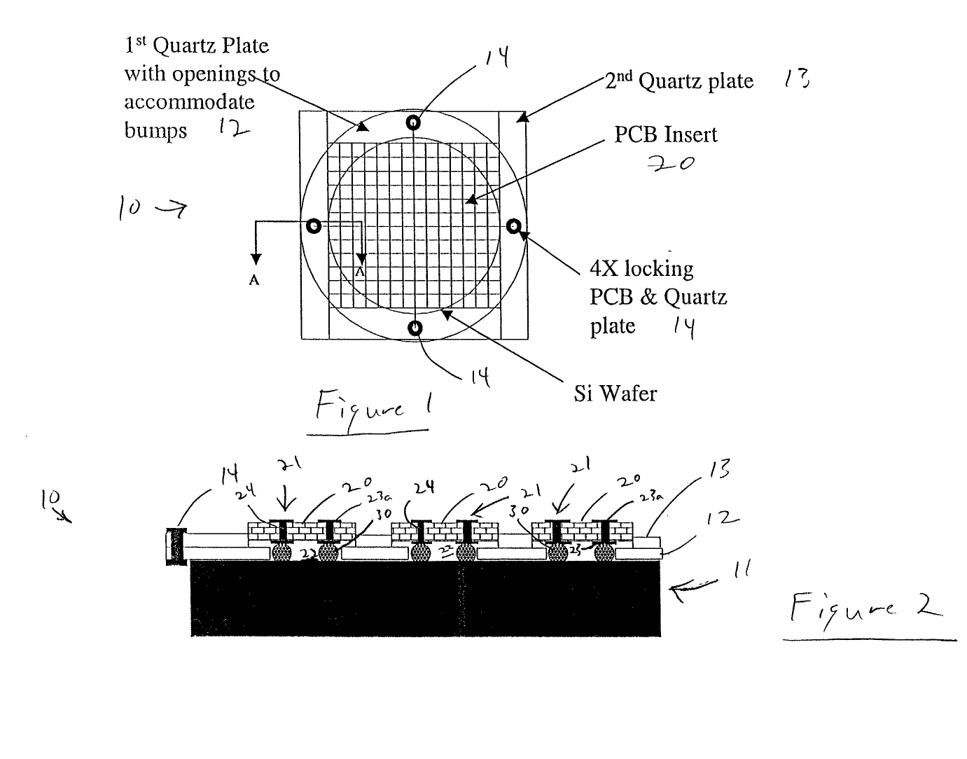

FIG. 1 illustrates a testing setup 10 for testing bumped wafers 11 according to an exemplary embodiment of the present invention. The test setup includes a first plate 12 and a second plate 13. Preferably, both plates are made of transparent material such as quartz. Examples of other types of material for the plates include glass and other solid but clear materials. The two plates are coupled to one another with coupling devices 14, preferably at four distinct locations to provide four point locking between the two plates. Examples of coupling devices include dowels, rivets, permanent glue, screws, etc. Those skilled in the art will understand that it may be possible to construct the two plates as a one-piece unit.

At least one interposer, preferably a test printed circuit board (PCB) insert, 20 is contained within the second quartz plate. Insert 20 is placed within the second quartz plate loosely such that it “floats,” i.e., it is not fixedly attached to the second quartz plate. The test PCB insert includes contacts 21 that are preferably gold plated although other suitable material may also be used. The contacts align with the openings 22 provided in the first plate when the two plates are coupled together. The solder bump contact 21 is made up of two contact plates 23 (preferably gold) coupled with a plated via 24.

In use, the test setup is placed on a bumped wafer 11 such that the solder bumps 30 on the bumped wafer extend into the openings 22 defined within the first plate and contact the solder bump contacts 21. The plate 23a on the solder bump contact opposite the plated via then contacts the test equipment (not shown). The test equipment may be any one of the standard probers or standard ATE set-ups known in the industry with needle or other types of probes that contact the top gold plated contact 23a on the PCB The wafer is preferably loaded from the bottom into testing setup 10. Generally, an automated handler, as is known in the industry, grabs the wafer and brings it to the testing set-up. Alignment of the wafer and the quartz plate is preferably done visually with a lens system that uses alignment marks (not shown) on the wafer by viewing the alignment marks through the quartz plates. When it is aligned, the wafer is lifted to testing setup 10 and the floating PCB insert is now resting on the bumps guided by the second quartz plate wall. The PCB insert tolerances enables it to tilt slightly to make contact with uneven bumps within the specification. An exemplary range of tolerances for the PCB insert is ±10 microns.

According to a preferred embodiment of the invention, testing setup 10 is preferably symmetrical. Thus, wafers may be loaded into the testing setup such that “quadrants” of the wafer are tested. For example, a bumped wafer may be loaded into testing setup 10 such that half the wafer is in contact with PCB inserts. Once this half of the wafer has been tested, the testing setup with the wafers may be removed from the testing apparatus, the bumped wafer lowered from the testing setup 10 and rotated 180 degrees so that the untested half of the wafer is now aligned in testing setup 10. The testing setup 10 with the bumped wafer will then be placed in contact again with the testing apparatus so that the second half of the wafer may be tested. Thus, one half, one quarter, one third, one eighth, etc. of the wafer may be tested at a time if desired.

The present invention thus provides an improved test setup allowing for high speed testing that reduces the final test time. The setup includes minimal test hardware setup. It allows for simple wafer level testing without requiring fine alignment of the wafer. Furthermore, the test setup in accordance with the present invention allows for the implementation of hot and cold testing in the wafer level test environment.

Additionally, the test setup does not use expensive membrane probes. Since membrane probes are not used, the test setup in accordance with the present invention does not have a tool life limitation because upon the number of touchdowns of the membrane probes. The test setup hardware is reusable for the same semiconductor device/bump layout wafer. Thus, testing setup 10 and the plates are unique to the semiconductor device/bump layout wafer. For various semiconductor devices/bump layout wafers, the plates and PCB inserts may need to be redesigned. Generally, the setup will be customized for each product.

Furthermore, the hardware for the test setup provides easy maintenance of the test PCB inserts due to pad oxidation. Furthermore, the inserts are preferably symmetrical and thus, orientation within the quartz plates will not be an issue.

Finally, the system and method in accordance with the present invention may be used to identify bumped wafers with lower bump height as rejects and thus help maintain a high outgoing quality. Such information allows low bump height issues to be brought to the attention of wafer bumping suppliers.

Although the invention has been described with reference to specific exemplary embodiments, it will be appreciated that is intended to cover all modifications and equivalents within the scope of the appended claims.

What is claimed is:

1. A method of testing a bumped wafer, the method comprising:
providing a bumped wafer including a plurality of solder bumps;
providing a test set-up comprising a first plate and a second plate coupled thereto, the first plate including openings to accommodate the solder bumps and the second plate including a test printed circuit board insert contained therein, the test printed circuit board insert including solder bump contacts;
contacting the test set-up with the bumped wafer such that the solder bumps are within the openings and the solder bump contacts contact the solder bumps; and
contacting the solder bump contacts with a test apparatus.

2. A method in accordance with claim 1 wherein the first plate is a quartz plate.

3. A method in accordance with claim 1 wherein the second plate is a quartz plate.

4. A method in accordance with claim 3 wherein the first plate is a quartz plate.

5. A method in accordance with claim 1 wherein solder bump contacts are gold plated.

6. A method in accordance with claim 5 wherein the first plate is a quartz plate.

7. A method in accordance with claim 6 wherein the second plate is a quartz plate.

8. A method in accordance with claim 1 wherein the method of testing includes hot and cold testing.

9. A bumped wafer test set-up for testing at least one bumped wafer that includes a plurality of solder bumps, the set-up comprising:
a first plate including openings to accommodate the solder bumps;
a second plate coupled to the first plate; and
a test printed circuit board insert within the second plate, the test printed circuit board including solder bump contacts;
wherein the solder bumps project into the openings and contact the solder bump contacts when the set-up is in use.

10. A bumped wafer test set-up in accordance with claim 9 wherein the first plate is a quartz plate.

11. A bumped wafer test set-up in accordance with claim 9 wherein the second plate is a quartz plate.

12. A bumped wafer test set-up in accordance with claim 11 wherein the first plate is a quartz plate.

13. A bumped wafer test set-up in accordance with claim 9 wherein the solder bump contacts are gold plated.

14. A bumped wafer test set-up in accordance with claim 13 wherein the first plate is a quartz plate.

15. A bumped wafer test set-up in accordance with claim 14 wherein the second plate is a quartz plate.

16. A method for testing a bumped wafer, the method comprising:
providing a bumped wafer including a plurality of solder bumps;
providing a test set-up comprising at least one plate, the plate including openings to accommodate the solder bumps and at least one interposer aligned with the openings, the interposer including solder bump contacts;
contacting the test set-up with the bumped wafer such that the solder bumps are within the openings and the solder bump contacts contact the solder bumps; and
contacting the solder bump contacts with a test apparatus.

17. A method in accordance with claim 16 wherein the bumped wafer is brought into contact with the test set-up by bringing the bumped wafer under the test-set-up and then raising the bumped wafer.

18. A method in accordance with claim 16 wherein the solder bump contacts are contacted with the test apparatus with probe needles of the test apparatus.

19. A bumped wafer test set-up for testing at least one bumped wafer that includes a plurality of solder bumps, the set-up comprising:
at least one plate including openings to accommodate the solder bumps; and
at least one interposer aligned with the openings, the interposer including solder bump contacts;
wherein the solder bumps project into the openings and contact the solder bump contacts when the set-up is in use.

20. A bumped wafer test set-up in accordance with claim 19 wherein the at least one plate is a quartz plate.

21. A bumped wafer test set-up in accordance with claim 19 wherein the at least one plate is a glass plate.

22. A bumped wafer test set-up in accordance with claim 19 wherein the solder bump contacts are gold plated.
